(19) United States
(12) Patent Application Publication
(10) Pub. No.: US 2026/0086119 A1
(43) Pub. Date: Mar. 26, 2026

(54) ELECTRICAL CONNECTION DEVICE

(71) Applicant: Kabushiki Kaisha Nihon Micronics, Tokyo (JP)

(72) Inventors: Ken HASEGAWA, Aomori (JP); Tsuyoshi Muramoto, Oita (JP); Kentaro Tanaka, Oita (JP); Sho Kawano, Oita (JP); Masaki Goto, Oita (JP)

(73) Assignee: Kabushiki Kaisha Nihon Micronics, Tokyo (JP)

(21) Appl. No.: 19/332,705

(22) Filed: Sep. 18, 2025

(30) Foreign Application Priority Data
Sep. 24, 2024 (JP) 2024-165591

(51) Int. Cl. G01R 1/073; H01L 23/373; H01L 23/538

(52) U.S. Cl. CPC G01R 1/07328; H10W 40/25; H10W 70/614

(57) ABSTRACT

An electrical connection device includes: a printed circuit board; a probe head holding a plurality of probes, each of the probes having a proximal end portion that is electrically connected to the printed circuit board and a distal end portion that comes into contact with an inspection target object; and a fix base provided below the printed circuit board and partially fixed to an upper surface of the probe head. The fix base and the printed circuit board are relatively movable according to thermal expansion.

### CROSS-REFERENCE TO RELATED APPLICATION

The present application is based on, and claims priority from Japanese Patent Application No. 2024-165591, filed on Sep. 24, 2024, the entire contents of which are incorporated herein by reference.

### TECHNICAL FIELD

The present application relates to an electrical connection device used for inspecting an electrical characteristic of an object to be inspected.

### BACKGROUND

In order to measure electrical characteristics of objects to be inspected such as an integrated circuit, electrical connection devices that electrically connect the objects to be inspected and inspection devices are used. As the electrical connection devices, a configuration in which a probe head holding a probe is attached to a printed circuit board on which a land electrically connected to the probe is arranged is used.

An electrical characteristic of an inspection target object can be measured by bringing individual probes held by a probe head into contact with a wafer pad of the inspection target object. In addition, a space transformer is fixed between the probe head and the printed circuit board in order to convert a wiring pitch between the individual probes and printed circuit board.

The space transformer is fixed by a fixing member connected to the printed circuit board, and the probe head is fixed to the space transformer (see JP 2009-521674 A). Therefore, the electrical characteristic of the inspection target object is measured in a state in which the printed circuit board, the space transformer, and the probe head are fixed to each other. In the measurement of the electrical characteristic of the inspection target object, a measurement instrument may generate heat due to Joule heat or the like and enter a high temperature state. In addition, there is also a so-called burn-in measurement that is performed by intentionally increasing a temperature of the inspection target object to a high temperature.

### SUMMARY

In a support structure of the space transformer in the related art, the printed circuit board, the probe head, and the space transformer are fixed, and the probe head and the space transformer have different thermal expansion amounts. Therefore, a problem arises in that each probe and each contact terminal provided on the printed circuit board are misaligned.

In addition, since the wafer pad and the printed circuit board have different thermal expansion amounts, a problem arises in that it is difficult to align each probe and each wafer pad.

The present application is made to solve such problems in the related art, and an object thereof is to provide an electrical connection device capable of enabling appropriate electrical connection between a wafer pad and a printed circuit board.

An electrical connection device according to an embodiment includes: a printed circuit board; a probe head holding a plurality of probes, each of which has a proximal end portion that is electrically connected to the printed circuit board and a distal end portion that comes into contact with an inspection target object; and a fix base provided below the printed circuit board and partially fixed to an upper surface of the probe head. The fix base and the printed circuit board are relatively movable according to thermal expansion.

According to the embodiment, it is possible to enable appropriate electrical connection between the wafer pad and the printed circuit board.

### BRIEF DESCRIPTION OF DRAWINGS

FIG. 1A is a cross-sectional view illustrating a configuration of an electrical connection device according to an embodiment and illustrates a state of the electrical connection device in a steady state (a low temperature state).

FIG. 1B is a cross-sectional view illustrating a configuration of the electrical connection device according to the embodiment and illustrates a state of the electrical connection device in a high temperature state.

FIG. 2 is a perspective view of the electrical connection device according to the embodiment from below.

FIG. 3A is a plan view for illustrating a structure for providing a fix base and a printed circuit board to be relatively movable according to thermal expansion in the electrical connection device according to the embodiment.

FIG. 3B is a view illustrating a cross section taken along line A-A in FIG. 3A.

FIG. 4A is a plan view for illustrating through-holes of the printed circuit board provided in the electrical connection device according to the embodiment.

FIG. 4B is an enlarged view of a through-hole provided in region A1 in FIG. 4A.

FIG. 4C is an enlarged view of a through-hole provided in region A2 in FIG. 4A.

FIG. 5A is a view illustrating a modification example of a support member provided in the electrical connection device according to the embodiment.

FIG. 5B is a view illustrating a modification example of the support member provided in the electrical connection device according to the embodiment.

FIG. 6A is an illustrative view for illustrating connection between the printed circuit board and an interposer provided in the electrical connection device according to the embodiment and is a side view at a low temperature.

FIG. 6B is an illustrative view for illustrating connection between the printed circuit board and the interposer provided in the electrical connection device according to the embodiment and is a side view at a high temperature.

FIG. 6C is an enlarged plan view of a contact state at the low temperature illustrated in FIG. 6A.

FIG. 6D is an enlarged plan view of a contact state at the high temperature illustrated in FIG. 6B.

FIG. 7A is an enlarged plan view of a contact state between a printed circuit board and an interposer provided in an electrical connection device according to Modification Example 1 at a low temperature.

FIG. 7B is an enlarged plan view of a contact state between the printed circuit board and the interposer provided in the electrical connection device according to Modification Example 1 at a high temperature.

FIG. 7C is an enlarged plan view of a contact state between a printed circuit board and an interposer provided in an electrical connection device according to Modification Example 2 at a low temperature.

FIG. 7D is an enlarged plan view of a contact state between the printed circuit board and the interposer provided in the electrical connection device according to Modification Example 2 at a high temperature.

### DETAILED DESCRIPTION

Next, an embodiment will be described with reference to the drawings. In the following description of the drawings, the same or similar portions are denoted by the same or similar reference numerals. However, it should be noted that the drawings are schematic, and dimensional ratios or the like of individual portions are different from actual ones. In addition, it is a matter of course that there is a portion having a dimensional relationship or ratio different between the drawings. The embodiments to be described below exemplify a device for embodying the technical idea of the invention, and the embodiments of the invention are not intended to limit a material, a shape, a structure, arrangement, and the like of a component to those to be described below.

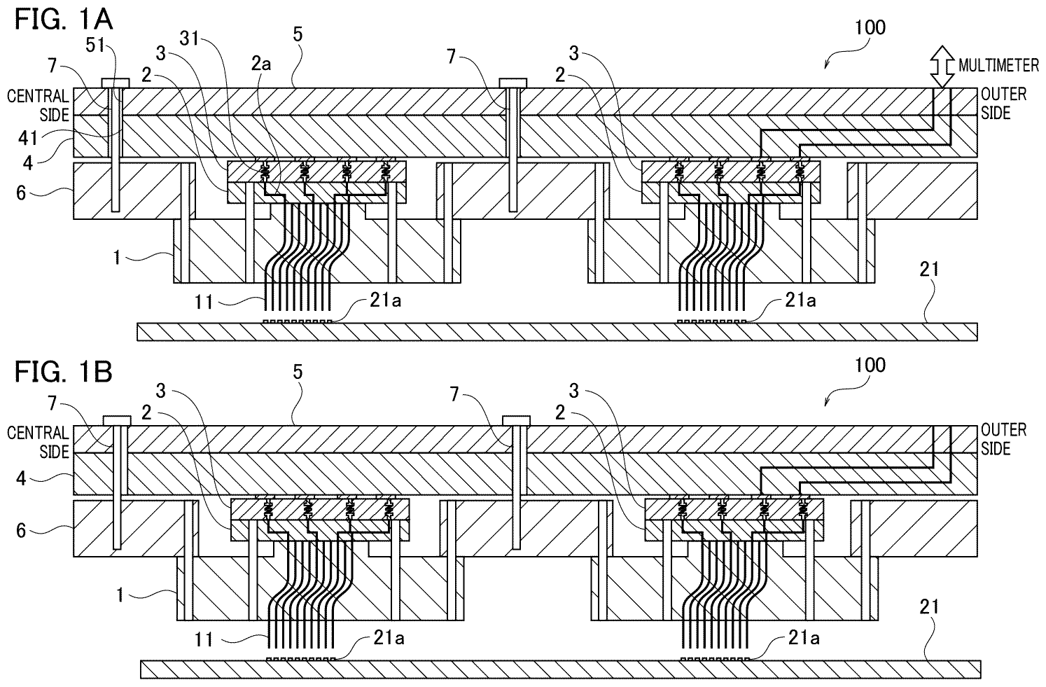

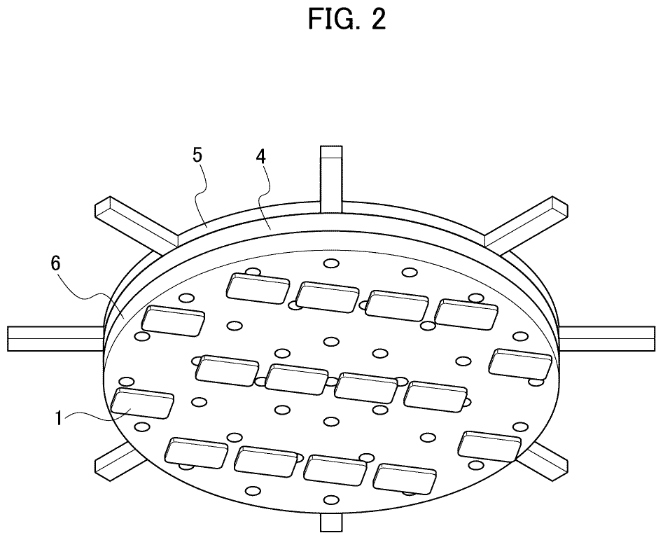

FIG. 1A is a cross-sectional view illustrating a configuration of an electrical connection device 100 according to an embodiment and illustrates a state of the electrical connection device 100 in a steady state (a low temperature state). FIG. 1B is a cross-sectional view illustrating a configuration of the electrical connection device 100 according to the embodiment and illustrates a state of the electrical connection device 100 in a high temperature state. FIG. 2 is a perspective view of the electrical connection device 100 according to the embodiment from below.

As illustrated in FIGS. 1A and 1B, the electrical connection device 100 includes a probe head 1, a space transformer 2, an interposer 3, a printed circuit board 4, a reinforcement plate 5, and a fix base 6. In addition, as illustrated in FIG. 2, the printed circuit board 4, the reinforcement plate 5, and the fix base 6 are formed in a disk shape. Note that, in the following description, a side of the reinforcement plate 5 in FIGS. 1A and 1B (an upper side in the drawings) is defined as an upward direction, and the opposite side thereto (a lower side in the drawings) is defined as a downward direction. In addition, a direction of a plane orthogonal to the up-down direction is defined as a planar direction. In FIGS. 1A and 1B, in the planar direction, the left side on the paper surface is a central side of each member formed in a disk shape, and the right side on the paper surface is an outer side of a circle.

The probe head 1 holds a plurality of probes 11. Distal end portions of the respective probes 11 are connected to individual pads 21a of a wafer 21 which is an inspection target object. That is, in an electrical inspection of the wafer 21 in the electrical connection device 100, for example, the probe head 1 and the wafer 21 are aligned in a state in which the wafer 21 is held on a chuck table (not illustrated), and an electrical signal is caused to flow through each of the probes 11. This enables the electrical connection device 100 to inspect an electrical connection state of the wafer 21 which is the inspection target object. That is, the probe head 1 holds the plurality of probes, each of which has a proximal end portion electrically connected to the printed circuit board 4 and a distal end portion that comes into contact with the inspection target object (the pad 21a).

An inside of the probe head 1 has a hollow structure. A plurality of through-holes into which the probes 11 are inserted are formed in an upper surface member and a lower surface member. The proximal end portions of the probes 11 inserted into the through-holes are connected to wirings of the space transformer 2, and the proximal end portions of the inserted probes 11 are connected to the individual pads 21a of the wafer 21 which is the inspection target object.

The space transformer 2 is interposed between the printed circuit board 4 and the probe head 1 and converts wiring pitches of the proximal end portions of the respective probes 11 held by the probe head 1. A lower surface of the space transformer 2 is in contact with the proximal end portions of the probes 11. An upper surface of the space transformer 2 faces the printed circuit board 4 with the interposer 3 interposed therebetween.

The interposer 3 is a substrate for enabling the upper surface and the lower surface to be electrically connected and electrically connects wirings 2a arranged in the space transformer 2 and the printed circuit board 4 by contacts 31. As the contact 31, for example, an elastic member such as a pogo pin or conductive rubber can be used. Note that the contact 31 is not limited to the elastic member, and a wiring or the like may be used.

The printed circuit board 4 is a base for inspecting the electrical connection state of the wafer 21 which is the inspection target object. The printed circuit board 4 has a through-hole 41 penetrating the printed circuit board in the up-down direction in order to allow a suspension member 7 which will be described below to be inserted thereinto.

The reinforcement plate 5 is formed of, for example, stainless steel or the like and is provided to have a lower surface of the reinforcement plate 5 which is in contact with an upper surface of the printed circuit board 4. This enables the printed circuit board 4 to be reinforced in terms of strength. The reinforcement plate 5 has a through-hole 51 penetrating the reinforcement plate in the up-down direction at the same position as the through-hole 41 for allowing the suspension member 7 which will be described below to be inserted thereinto.

The fix base 6 is fixed to a lower end portion of the suspension member 7 provided to penetrate the through-hole 51 of the reinforcement plate 5 which will be described later and the through-hole 41 of the printed circuit board 4, and is suspended and supported by the suspension member 7 with a predetermined gap provided below the printed circuit board 4. In addition, a part of a lower surface of the fix base 6 is fixed to a part of an upper surface of the probe head 1.

A material and a thickness of the fix base 6 are set to have a thermal expansion amount equal to a thermal expansion amount of the wafer 21 which is the inspection target object. The thickness of the fix base 6 is selected such that, in terms of thermal expansion coefficients of the fix base 6 and the wafer 21, the thermal expansion amounts of both members are equal. The thickness of the fix base is selected in consideration of a magnitude of radiant heat or the like from the chuck table on which the wafer 21 is held. Note that the thermal expansion coefficients of the printed circuit board 4 and the reinforcement plate 5 are higher than the thermal expansion coefficient of the fix base 6.

As illustrated in FIG. 1A, in a steady state (a low temperature state), the probe head 1 and the wafer 21 are aligned such that the distal end portions of the respective probes 11 are connected to the individual pads 21a of the wafer 21 which is the inspection target object.

As illustrated in FIG. 1B, in a high temperature state, each member provided in the electrical connection device 100 thermally expands from the central side of the circle toward the outer side (the right side on the paper surface). Here, since the fix base 6 and the printed circuit board 4 are provided to be relatively movable according to thermal expansion, the fix base 6 and the probe head 1 fixed to the fix base 6 thermally expand to conform to the thermal expansion of the wafer 21. Therefore, it is possible to maintain a state in which the distal end portions of the respective probes 11 are connected to the individual pads 21a of the wafer 21. In addition, the thermal expansion coefficients of the printed circuit board 4 and the reinforcement plate 5 are higher than the thermal expansion coefficient of the fix base 6. Therefore, in the high temperature state illustrated in FIG. 1B, the suspension member 7 approaches a left wall surface (the central side) in the through-hole 41.

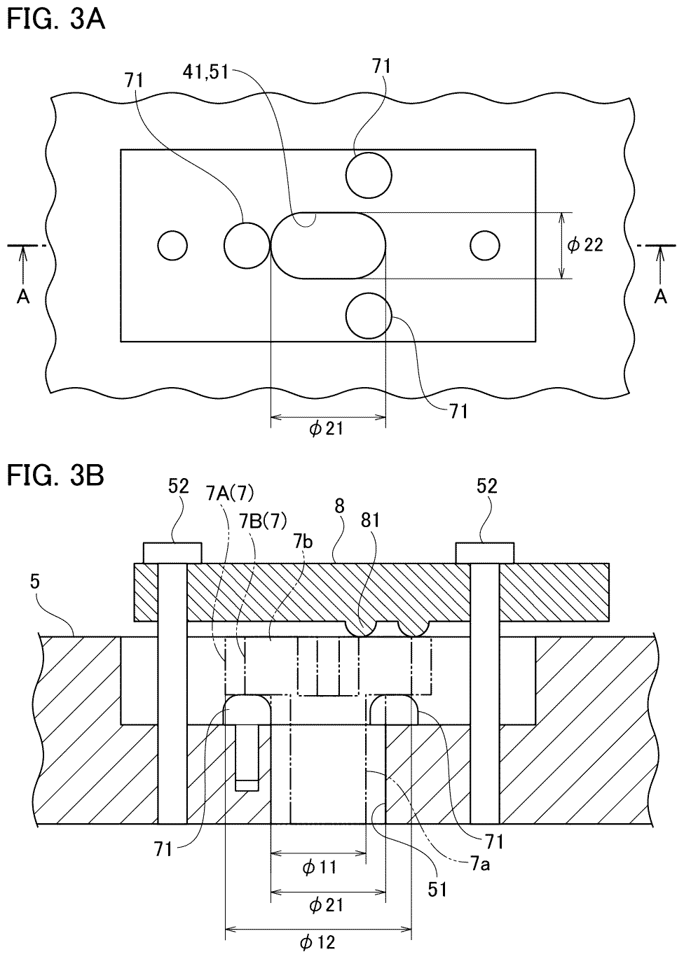

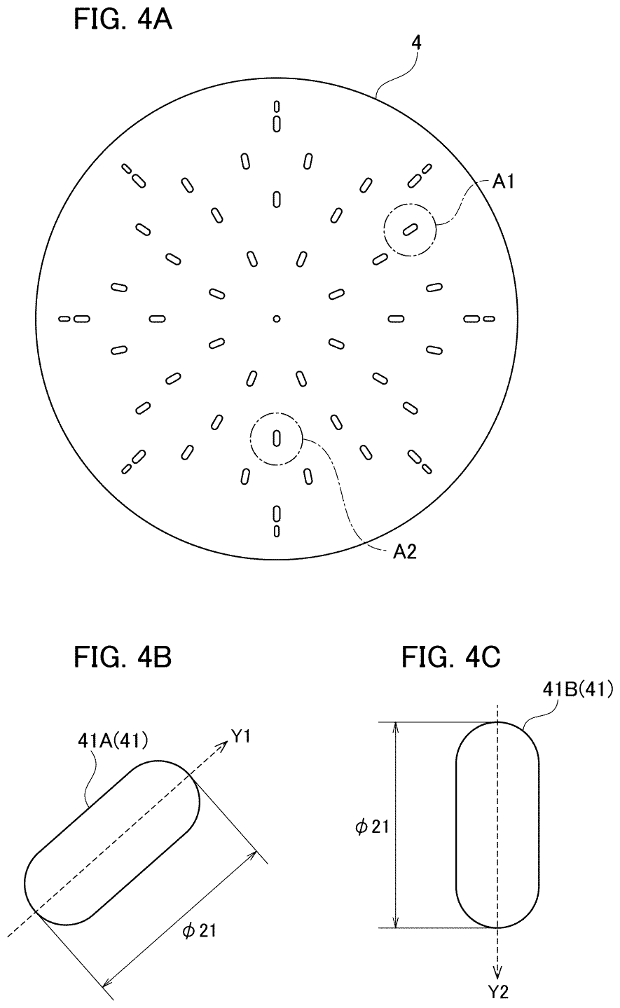

FIG. 3A is a plan view for illustrating a structure for providing the fix base 6 and the printed circuit board 4 to be relatively movable according to thermal expansion in the electrical connection device 100 according to the embodiment. FIG. 3B is a view illustrating a cross section taken along line A-A in FIG. 3A. Note that, in FIG. 3A, for the sake of description, the suspension member 7 and a configuration provided above the reinforcement plate 5 are omitted. FIG. 4A is a plan view for illustrating the through-holes 41 of the printed circuit board 4 provided in the electrical connection device 100 according to the embodiment. FIG. 4B is an enlarged view of the through-hole 41 (here, referred to as a through-hole 41A) provided in region A1 in FIG. 4A. FIG. 4C is an enlarged view of the through-hole 41 (here, referred to as a through-hole 41B) provided in region A2 in FIG. 4A.

As illustrated in FIG. 3B, a lid 8 is arranged with a predetermined gap from an upper portion of the reinforcement plate 5, and the lid 8 is fixed to the reinforcement plate 5 from above with fixing bolts 52. At this time, in order to provide the gap between the reinforcement plate 5 and the lid 8, an elastic material 81 may be arranged between the reinforcement plate 5 and the lid 8 and fixed with the fixing bolts 52, and then the elastic material 81 may be removed or left as it is.

As described above, the reinforcement plate 5 has the through-hole 51 penetrating the reinforcement plate 5 in the up-down direction, and the printed circuit board 4 has the through-hole 41 penetrating the printed circuit board 4 in the up-down direction at the same position as the through-hole 51 in the planar direction.

As illustrated in FIG. 3A, a cross-sectional shape of the through-hole 41 and the through-hole 51 is an elliptical shape in which a thermal expansion direction (a crosswise direction on the paper surface) of the fix base 6 is a major axis such that slidable movement is performed according to the thermal expansion of the fix base 6. An inner diameter of the major axis of the elliptical shape is set to Φ21.

In FIG. 4A, the thermal expansion direction of the fix base 6 is a direction from the center of the circle on the printed circuit board 4 toward the outer side. Specifically, as illustrated in FIG. 4B, a direction of an arrow Y1 is the thermal expansion direction of the fix base 6 in the through-hole 41 (here, referred to as the through-hole 41A) provided in region A1 in FIG. 4A, and as illustrated in FIG. 4C, a direction of an arrow Y2 is the thermal expansion direction of the fix base 6 in the through-hole 41 (here, referred to as the through-hole 41B) provided in region A2 in FIG. 4A.

As illustrated in FIG. 4B, a cross-sectional shape of the through-hole 41A is an elliptical shape having an inner diameter Φ21 and having the major axis in a Y1 direction which is the thermal expansion direction of the fix base 6. As illustrated in FIG. 4C, a cross-sectional shape of the through-hole 41B is an elliptical shape having an inner diameter Φ21 and having the major axis in a Y2 direction which is the thermal expansion direction of the fix base 6.

As illustrated in FIG. 3B, the suspension member 7 has a main body portion 7a having an outer diameter Φ11 sufficiently smaller than the inner diameter Φ21 to be inserted into the through-hole 41 and the through-hole 51 and slidable in the thermal expansion direction (the crosswise direction on the paper surface) of the fix base 6 in an inserted state, and a top portion 7b having an outer diameter Φ12 larger than the inner diameter Φ21.

Three support members 71 having respective hemispherical top portions are arranged in the vicinity of the through-hole 51, and a lower portion of the top portion 7b of the suspension member 7 is brought into contact with the top portions of the three support members 71, thereby being suspended and supported.

In the electrical connection device 100 having such a configuration, in a case where the fix base 6 thermally expands in a high temperature state, the main body portion 7a of the suspension member 7 fixed to the fix base 6 slides in the thermal expansion direction within the inner diameter Φ21. The probe head 1 fixed to the fix base 6 also thermally expands to conform to the thermal expansion of the wafer 21, whereby interval lengths of the individual probes 11 held by the probe head 1 also conform to the thermal expansion of the wafer 21. This enables a state in which the distal end portions of the respective probes 11 held by the probe head 1 are electrically connected to the individual pads 21a of the wafer 21 to be maintained. Thus, the electrical connection device 100 can appropriately perform electrical measurement of a circuit formed in the wafer 21 even in the high temperature state.

In an example illustrated in FIG. 3B, a steady position 7A which is a position of the suspension member 7 in the steady state (the low temperature state) and an expanded position 7B which is a position of the suspension member 7 in the high temperature state are illustrated. When the fix base 6 thermally expands, the suspension member 7 slides from the steady position 7A to the expanded position 7B according to the thermal expansion amount of the fix base 6.

Note that, here, a configuration has been described, in which the three support members 71 having respective hemispherical top portions are arranged in the vicinity of the through-hole 51, and the lower portion of the top portion 7b of the suspension member 7 is suspended and supported by being brought into contact with the top portions of the three support members 71. However, the support members 71 are not limited to this shape.

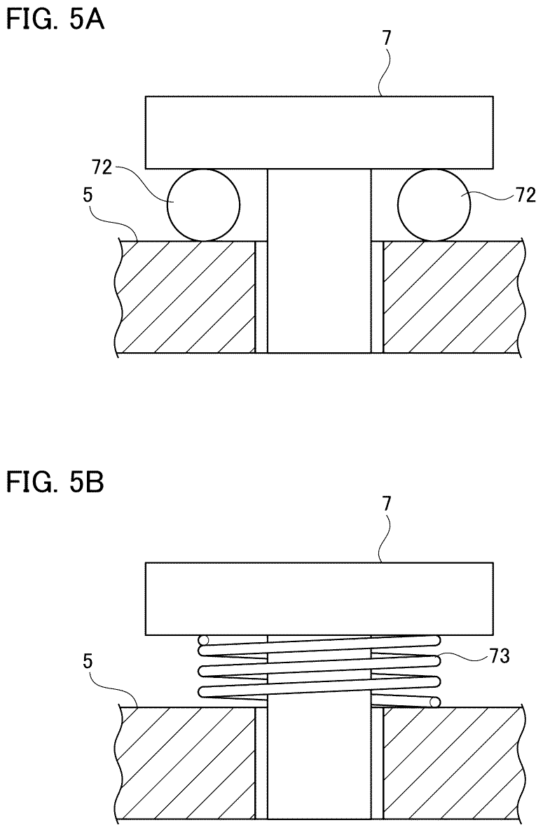

For example, as illustrated in FIG. 5A, a support member 72 having a circular columnar shape that can roll in the thermal expansion direction (the crosswise direction on the paper surface) may be provided. In addition, the number of the support members 72 is not limited to three and may be three or more as long as the suspension member 7 can be suspended and supported. Further, the support member 72 has the circular columnar shape that can roll in the thermal expansion direction (the crosswise direction on the paper surface), but may have a spherical shape.

In addition, as illustrated in FIG. 5B, the suspension member 7 may be suspended and supported to be slidable in the thermal expansion direction (the crosswise direction on the paper surface) by a support member 73 which is biasing means.

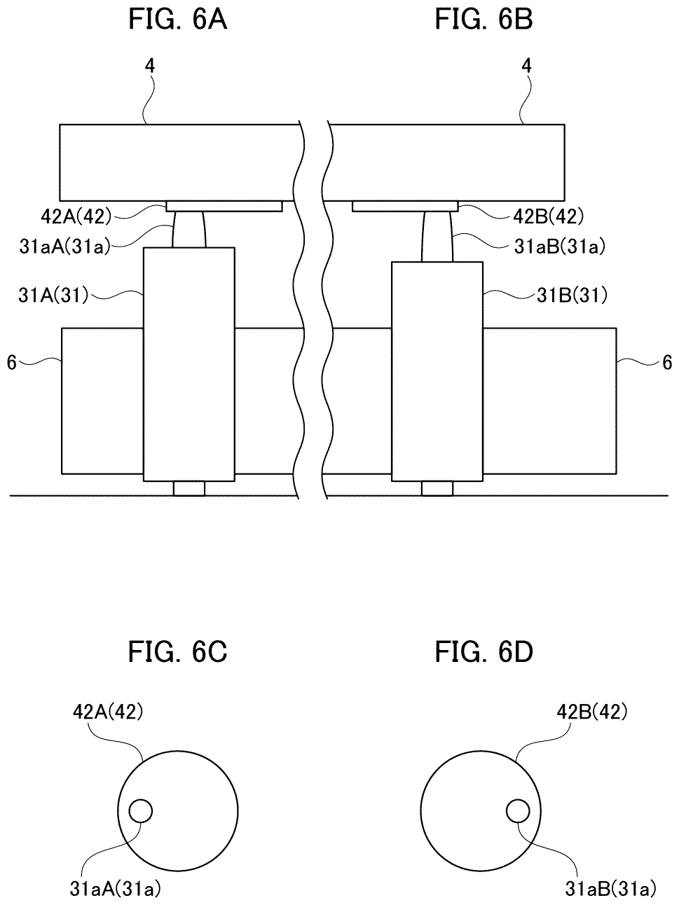

FIG. 6A is an illustrative view for illustrating connection between the printed circuit board 4 and the interposer 3 provided in the electrical connection device 100 according to the embodiment and is a side view at a low temperature. FIG. 6B is an illustrative view for illustrating connection between the printed circuit board 4 and the interposer 3 provided in the electrical connection device 100 according to the embodiment and is a side view at a high temperature. FIG. 6C is an enlarged plan view of a contact state at the low temperature illustrated in FIG. 6A. FIG. 6D is an enlarged plan view of a contact state at the high temperature illustrated in FIG. 6B.

As illustrated in FIGS. 6A and 6B, a land 42 is provided on the lower surface of the printed circuit board 4. Here, the land 42 located in FIG. 6A is referred to as a land 42A (42), and the land 42 located in FIG. 6B is referred to as a land 42B (42).

A lower end portion of the contact 31 is in contact with an upper end portion of the wiring 2a arranged in the space transformer 2. In addition, a distal end portion 31a is provided at an upper portion of the contact 31, and the distal end portion 31a is electrically connected to the land 42 and is provided to slide together with the upper end portion of the wiring 2a due to thermal expansion of the probe head 1. Here, the contact 31 located in FIG. 6A is referred to as a contact 31A (31), the distal end portion 31a is referred to as a distal end portion 31aA (31a), the contact 31 located in FIG. 6B is referred to as a contact 31B (31), and the distal end portion 31a is referred to as a distal end portion 31aB (31a).

The land 42 is formed in a shape allowing contact to be maintained even in a case where the distal end portion 31a of the contact 31 slides in the thermal expansion direction due to the thermal expansion of the probe head 1.

Specifically, as illustrated in FIGS. 6A and 6C, at the low temperature, the distal end portion 31aA (31a) of the contact 31A (31) and the land 42A (42) are in contact with each other at a position of an end portion of the left end in the crosswise direction on the paper surface. In addition, as illustrated in FIGS. 6B and 6D, in a case where the distal end portion 31aB (31a) of the contact 31B (31) slides in the thermal expansion direction (the crosswise direction on the paper surface) due to the thermal expansion of the probe head 1 at the high temperature, the distal end portion 31aB (31a) of the contact 31B (31) and the land 42B (42) are in contact with each other at a position of an end portion of the right end in the crosswise direction on the paper surface.

As described above, the land 42 is formed in a shape in which both a contact position with the contact 31 at a low temperature and a contact position with the contact 31 at a high temperature of the probe head 1 are located at end portions of the land 42. This enables the land 42 to maintain contact therewith even in a case where the distal end portion 31a of the contact 31 slides in the thermal expansion direction due to the thermal expansion of the probe head 1.

Note that, here, an example has been described, in which the land 42 is formed in a shape in which both the contact position with the contact 31 at a low temperature and the contact position with the contact 31 at a high temperature of the probe head 1 are located at end portions of the land; however, the invention is not limited thereto.

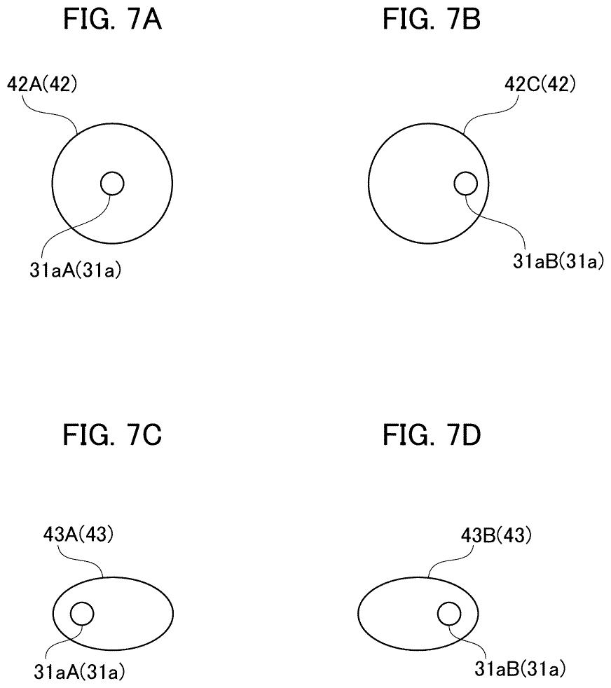

FIG. 7A is an enlarged plan view of a contact state between the printed circuit board 4 and the interposer 3 provided in the electrical connection device 100 according to Modification Example 1 at a low temperature, and FIG. 7B is an enlarged plan view of a contact state at a high temperature.

As illustrated in FIG. 7A, at the low temperature, the distal end portion 31aA (31a) of the contact 31A (31) and the land 42A (42) are in contact with each other at a center position in the crosswise direction on the paper surface. As illustrated in FIG. 7B, in a case where the distal end portion 31aB (31a) of the contact 31B (31) slides in the thermal expansion direction (the crosswise direction on the paper surface) due to the thermal expansion of the probe head 1 at the high temperature, the distal end portion 31aB (31a) of the contact 31B (31) and the land 42B (42) are in contact with each other at the position of the end portion of the right end in the crosswise direction on the paper surface.

FIG. 7C is an enlarged plan view of a contact state between the printed circuit board 4 and the interposer 3 provided in the electrical connection device 100 according to Modification Example 2 at a low temperature, and FIG. 7D is an enlarged plan view of a contact state at a high temperature.

As illustrated in FIGS. 7C and 7D, a land 43 is formed into an elliptical shape having a major axis in the thermal expansion direction (here, the crosswise direction on the paper surface) of the probe head 1. Here, the contact 31 located in FIG. 7C is referred to as the contact 31A (31), the distal end portion 31a is referred to as the distal end portion 31aA (31a), the contact 31 located in FIG. 7D is referred to as the contact 31B (31), and the distal end portion 31a is referred to as the distal end portion 31aB (31a). In addition, the land 43 located in FIG. 7C is referred to as a land 43A (43), and the land 43 located in FIG. 7D is referred to as a land 43B (43).

As illustrated in FIG. 7C, at the low temperature, the distal end portion 31aA (31a) of the contact 31A (31) and the land 43A (43) are in contact with each other at a position of an end portion of the left end in the crosswise direction on the paper surface. As illustrated in FIG. 7D, in a case where the distal end portion 31aB (31a) of the contact 31B (31) slides in the thermal expansion direction (the crosswise direction on the paper surface) due to the thermal expansion of the probe head 1 at the high temperature, the distal end portion 31aB (31a) of the contact 31B (31) and the land 43B (43) are in contact with each other at the position of the end portion of the right end in the crosswise direction on the paper surface.

This enables the land 43 to maintain contact therewith even in a case where the distal end portion 31a of the contact 31 slides in the thermal expansion direction due to the thermal expansion of the probe head 1.

The invention has been described according to the above-described embodiments; however, the description and the drawings that are a part of this invention should not be understood to limit the invention. This disclosure will make various alternative embodiments, examples, and operation techniques apparent to those skilled in the art.

1. An electrical connection device, comprising:
a printed circuit board;
a probe head holding a plurality of probes, each of the probes having a proximal end portion that is electrically connected to the printed circuit board and a distal end portion that comes into contact with an inspection target object; and
a fix base provided below the printed circuit board and partially fixed to an upper surface of the probe head, wherein
the fix base and the printed circuit board are relatively movable according to thermal expansion.

2. The electrical connection device according to claim 1, wherein
a material and a thickness of the fix base are set to have a thermal expansion amount equal to a thermal expansion amount of the inspection target object.

3. The electrical connection device according to claim 1, wherein
the printed circuit board has a through-hole penetrating the printed circuit board in an up-down direction, and
the electrical connection device further comprises a suspension member that has a lower end portion fixed to the fix base and is inserted into the through-hole to be suspended and supported.

4. The electrical connection device according to claim 3, wherein
a cross-sectional shape of the through-hole is an elliptical shape in which a thermal expansion direction of the fix base is a major axis such that slidable movement is performed according to the thermal expansion of the fix base.

5. The electrical connection device according to claim 4, wherein
an upper portion of the suspension member is suspended and supported slidably in the thermal expansion direction of the fix base with respect to the printed circuit board.

6. The electrical connection device according to claim 1, further comprising:
a space transformer that is interposed between the printed circuit board and the probe head and has a wiring that converts a wiring pitch of each of the probes; and
a contact that electrically connects an upper end portion of the wiring and a land provided on a lower surface of the printed circuit board and is provided to slide together with the upper end portion of the wiring due to thermal expansion of the probe head, wherein
the land is formed in a shape allowing contact to be maintained even in a case where a distal end portion of the contact slides in a thermal expansion direction due to thermal expansion of the probe head.

7. The electrical connection device according to claim 6, wherein
the land is formed in a shape in which both a contact position with the contact at a low temperature of the probe head and a contact position with the contact at a high temperature of the probe head are located at end portions of the land.
